(19) United States
(12) Patent Application Publication
(10) Pub. No.: US 2013/0181191 A1
(43) Pub. Date: Jul. 18, 2013

(54) ELECTRONIC DEVICES INCLUDING BIO-POLYMERIC MATERIAL AND METHOD FOR MANUFACTURING THE SAME

(71) Applicants: Jenn-Chang Hwang, Hsinchu (TW); Chao-Ying Hsieh, Hsinchu (TW); Lung-Kai Mao, Hsinchu (TW); Chun-Yi Lee, Hsinchu (TW); Li-Shiuan Tsai, Hsinchu (TW); Cheng-Lung Tsai, Hsinchu (TW); Wei-Cheng Chung, Hsinchu (TW); Ping-Chiang Lyu, Hsinchu (TW)

(72) Inventors: Jenn-Chang Hwang, Hsinchu (TW); Chao-Ying Hsieh, Hsinchu (TW); Lung-Kai Mao, Hsinchu (TW); Chun-Yi Lee, Hsinchu (TW); Li-Shiuan Tsai, Hsinchu (TW); Cheng-Lung Tsai, Hsinchu (TW); Wei-Cheng Chung, Hsinchu (TW); Ping-Chiang Lyu, Hsinchu (TW)

(21) Appl. No.: 13/485,968

(22) Filed: Jun. 1, 2012

(30) Foreign Application Priority Data
Jan. 13, 2012 (TW) 101101562

(51) Int. Cl. H01L 51/10; H01L 21/02

(52) U.S. Cl. 257/40; 438/99; 438/381; 257/E51.006; 257/E21.008

(57) ABSTRACT

An electronic device including a bio-polymer material and a method for manufacturing the same are disclosed. The electronic device of the present invention comprises: a substrate; a first electrode disposed on the substrate; a bio-polymer layer disposed on the first electrode, wherein the bio-polymeric material is selected from a group consisting of wool keratin, collagen hydrolysate, gelatin, whey protein and hydroxypropyl methylcellulose; and a second electrode disposed on the biopolymer material layer. The present invention is suitable for various electronic devices such as an organic thin film transistor, an organic floating gate memory, or a metal-insulator-metal capacitor.

### CROSS REFERENCE TO RELATED APPLICATION

This application claims the benefits of the Taiwan Patent Application Serial Number 101101562, filed on Jan. 13, 2012, the subject matter of which is incorporated herein by reference.

### BACKGROUND OF THE INVENTION

1. Field of the Invention

The present invention relates to an electronic device including a bio-polymer material and a method for manufacturing the same. More specifically, the present invention relates to an organic thin film transistor including a bio-polymer material, an organic floating gate electrode memory including a bio-polymer material, and a metal-insulator-metal capacitor including a bio-polymer material; and a method for manufacturing the same.

2. Description of Related Art

As well known to those skilled in the art, transistors are applied in a wide variety of electronics to serve as switches for electric current. Different from mechanical valves, transistors are controlled by electric signals and the switch-speed of the transistors can be very fast. Transistors, for example, may be classified into bipolar junction transistors (BJTs) and field effect transistors (FETs). The field effect transistor comprises N-type organic thin film transistors (OTFT) and P-type organic thin film transistors, etc.

Usually, N-type or P-type of organic thin film transistors can be classified into top contact organic thin film transistors and bottom contact organic thin film transistors. As shown in FIG. 1A, a top contact organic thin film transistor comprises: a substrate 10; a gate electrode 11 locating on the substrate 10; a gate dielectric layer 12 disposed on the substrate 10 and covering the gate electrode 11; an organic semiconductor layer 13 covering the gate dielectric layer 12; and a source electrode 14 and a drain electrode 15 disposed on the organic semiconductor layer 13.

In addition, as shown in FIG. 1B, the bottom contact OTFT comprises: a substrate 10; a gate electrode 11 disposed on the substrate 10; a gate dielectric layer 12 disposed on the substrate 10 and covering the gate electrode 11; a source electrode 14 and a drain electrode 15 disposed on the gate dielectric layer 12; and an organic semiconductor layer 13 covering the gate dielectric layer 12, the source electrode 14, and the drain electrode 15.

In the conventional method for forming a gate dielectric layer, the dielectric material is sputtered on the substrate and the gate electrode to form the gate dielectric layer. However, the instrument for the sputtering process is very expensive and the process is complex. In addition, the common materials used in N-type or P-type organic semiconductor layers of the OTFT are pentacene, fullerene (C60), PTCDI-C8 (N,N′-Dioctyl-3,4,9,10-perylenedicarboximide), or F₁₆CuPc etc. Although pentacene, fullerene, PTCDI-C8, or F₁₆CuPc have good hole/electron field-effect mobility theoretically, they cannot match well with the dielectric material, so the hole/electron field-effect mobility thereof is low. For example, when silicon nitride is used as a material of the gate dielectric layer in the P-type pentacene OTFT, the hole field-effect mobility of the pentacene is lower than 0.5 cm²/V-sec; however, the hole field-effect mobility of pentacene is estimated to be 35-50 cm²/V-sec theoretically. Even when aluminum nitride is used as the material of the gate dielectric layer in the P-type pentacene OTFT, the hole field-effect mobility of the pentacene is about 1 cm²/V-sec. Hence, it is desirable to provide a material for the gate dielectric layer to match well with pentacene, fullerene, PTCDI-C8, or F₁₆CuPc.

The consumable electronic system is indispensably in this century. New organic electronic elements have the advantage of low weight, non-volatile property, and convenient portability so as to apply to extensive flexible electronic products. More specifically, these organic electronic elements are suitable for portable electronic products, such as cell phones, digital cameras, flash disks, etc.

One of the main techniques of organic electronic elements is conventional floating gate electrode non-volatile memory. As shown in FIG. 2, the floating gate electrode non-volatile memory comprises: a substrate 20; a gate electrode 21 disposed on the substrate 20; a gate dielectric layer 22 disposed on the substrate 10 and covering the gate electrode 21; a floating gate electrode 26 covers the gate dielectric layer 22; a dielectric layer 27 covers the floating gate electrode 26; an organic semiconductor layer 23 covers the dielectric layer 27; a source electrode 24 and a drain electrode 25 disposed on the organic semiconductor layer 23. As described above, the floating gate electrode 26 is used to store charge, and the material thereof can be metal, nanoparticle, or oxide.

In addition, metal-insulator-metal (MIM) capacitors are widely applied on digital and radio frequency (RF) circuit designs. Currently, several dielectric materials with high dielectric constant are developed to increase the capacitor density of the MIM capacitors and decrease the leakage current thereof. As shown in FIG. 3, a conventional MIM capacitor comprises: a substrate 30; a first electrode 31 disposed on the substrate 30; an insulating layer 32, disposed on the substrate 30 and covering the first electrode 31; and a second electrode 33 disposed on the insulating layer 32. Herein, the conventional dielectric material used in the insulating layer of the MIM capacitor can be TiN, TiO₂, SiO₂, and SiN. However, when the aforementioned dielectric material is serves as the insulating layer of the MIM capacitor, there are two disadvantage: first, the insulating layer is formed on the metal layer by use of a sputtering process or vacuum deposition equipment, which may cause the production cost and the process complexity to be increased; second, the MIM capacitor doesn't have flexibility, so the MIM capacitor cannot be applied to manufacture flexible electronic products.

Therefore, it is desirable to develop an electronic device including a novel bio-polymer material and a method for manufacturing the same, in order to prepare an efficient electronic device in a simple and cheap way, and apply to an organic thin film transistor, an organic floating gate electrode memory, or a metal-insulator-metal capacitor.

### SUMMARY OF THE INVENTION

The object of the present invention is to provide an electronic device including a bio-polymer material and a method for manufacturing the same, to prepare an electronic device with low cost.

To achieve the object, the electronic device of the present invention including a bio-polymer material comprises: a substrate; a first electrode disposed on the substrate; a bio-polymer layer disposed on the first electrode; and a second electrode disposed over the biopolymer material layer.

In the electronic devices of the present invention, the bio-polymer layer preferably has a single-layered structure or a multi-layered structure. The thickness of the overall bio-polymer layer can be adjusted by the number of the individual layers added, so as to obtain higher electron mobility or to reduce the leakage current.

In the present invention, the substrate can be a plastic substrate, a glass substrate, a quartz substrate, a silicon substrate, or a paper substrate. Preferably, the substrate is a plastic substrate. Using a plastic substrate to manufacture an electronic device, the electronic device has flexibility.

The material of the first electrode and the second electrode are independently selected from a group consisting of Al, Cu, Cr, Ag, Pt, Au, ZnO, and ITO. Preferably, the material is Au.

The material of the bio-polymer layer is not limited; it can be selected from bio-polymer protein material or cellulose polymer material. The bio-polymer protein material group may consist of wool keratin, collagen hydrolysate, gelatin, and whey protein; and cellulose polymer material can be hydroxypropyl methylcellulose and so on. Preferably, the material of the bio-polymer layer is selected from a group consisting of wool keratin, collagen hydrolysate, and gelatin; herein, the wool keratin can add glycerol selectively. The aforementioned bio-polymer materials have the advantage of low production cost, non-toxic environmentally, flexibility, etc. In the electronic device including a bio-polymer material of the present invention, the bio-polymer layer can be a dielectric layer or a gate dielectric layer.

According to the electronic device including a bio-polymer material of the present invention, the present invention can provide an organic thin film transistor. Herein, the bio-polymer material layer is a gate dielectric layer; the first electrode is a gate electrode disposed between the substrate and the gate dielectric layer, and the gate dielectric layer covers the gate electrode; and the second electrode comprises a source electrode and a drain electrode locating over the gate dielectric layer.

In the electronic device including a bio-polymer material of the present invention, the electronic device further comprises an organic semiconductor layer, wherein the organic semiconductor layer covers the gate dielectric layer. Preferably, the electronic device is a top contact organic thin film transistor; the organic semiconductor layer covers the entire surface of the gate dielectric layer, and the source electrode and the drain electrode locate on the organic semiconductor layer.

The material of the organic semiconductor layer is not limited; it can be selected from any material that has been used in P-type and N-type organic semiconductor layers in the art. Preferably, the material of a P-type organic semiconductor layer is pentacene or pentacene derivatives; the material of an N-type organic semiconductor layer is fullerene (C60), F₁₆CuPc, or perylene derivatives. The perylene derivatives can be PTCDI-C8 (N,N′-Dioctyl-3,4,9,10-perylenedicarboximide).

In the electronic device including a bio-polymer material of the present invention, the electronic device further comprises an organic semiconductor layer, wherein the organic semiconductor layer covers the gate dielectric layer, the source electrode, and the drain electrode. Preferably, the electronic device is a bottom contact organic thin film transistor, the organic semiconductor layer covers the gate dielectric layer, the source electrode, and the drain electrode, and the source electrode and the drain electrode locate on the gate dielectric layer.

In the electronic device including a bio-polymer material of the present invention, the present invention can provide an N-type organic thin film transistor. Herein, the electronic device further comprises a buffering layer disposed on the gate dielectric layer, and the material of the buffering layer is not limited, preferably is pentacene. The thickness of the buffering layer can range from 1 nm to 20 nm, preferably ranging from 1 nm to 10 nm, and more preferably ranging from 1 nm to 3 nm.

In the present invention, the N-type organic thin film transistor can be a top contact structure; the organic semiconductor layer, the source electrode, and the drain electrode are disposed over the buffering layer. The N-type organic thin film transistor can be a bottom contact structure; the organic semiconductor layer disposes over the buffering layer, and the buffering layer covers the gate dielectric layer, the source electrode, and the drain electrode.

According to the electronic device including a bio-polymer material of the present invention, the present invention can provide an organic floating gate electrode memory. Herein, the electronic device further comprises a floating gate electrode disposed between the gate dielectric layer and the organic semiconductor layer, and the floating gate electrode locates on the gate-dielectric layer. The material of the floating gate electrode is made of nanoparticle, oxide, or alloy selected from a group consisting of Al, Cu, Cr, Ag, Pt, Au, Zn, In or Sn. Preferably, the material is gold nanoparticle.

In the electronic device including a bio-polymer material of the present invention, the electronic device further comprises a dielectric layer disposed between the floating gate electrode layer and the organic semiconductor layer, and the dielectric layer covers the floating gate electrode.

In the electronic device including a bio-polymer material of the present invention, the bio-polymer layer can be an insulating layer.

According to the electronic device including a bio-polymer material of the present invention, the present invention can provide a metal-insulator-metal capacitor. Herein, the first electrode disposes between the substrate and the insulating layer; the insulating layer covers the first electrode; and the second electrode is disposed over the insulating layer.

Moreover, the present invention provides a method for manufacturing an electronic device including a bio-polymer material, comprising the following steps: (A) providing a substrate; (B) forming a first electrode on the substrate; (C) coating the substrate having the first electrode formed thereon with a bio-polymer solution to obtain a bio-polymer layer on the substrate and the first electrode; and (D) forming a second electrode over the bio-polymer layer.

In the method for manufacturing an electronic device including a bio-polymer material of the present invention, the bio-polymer layer is a gate dielectric layer; the first electrode is a gate electrode; and the second electrode comprises a source electrode and a drain electrode.

The step (C) comprises the flowing steps: (C1) providing a bio-polymer solution; (C2) coating the substrate having the gate electrode formed thereon with the bio-polymer solution, or dipping the substrate having the gate electrode formed thereon into the bio-polymer solution; and (C3) drying the bio-polymer solution which is coated on the substrate to obtain a gate dielectric layer on the substrate and the electrode.

In the manufacturing method of the present invention, the step (D) further comprises forming an organic semiconductor layer over the gate dielectric layer.

According to the manufacturing method of the present invention, the present invention provides a method for manufacturing a top contact organic thin film transistor. In the step (D), the semiconductor layer covers the entire surface of the gate dielectric layer, and the source electrode and the drain electrode are disposed on the organic semiconductor layer so as to obtain a top contact organic thin film transistor.

According to the manufacturing method of the present invention, the present invention provides a method for manufacturing a bottom contact organic thin film transistor. In the step (D), the source electrode and the drain electrode are disposed on the gate dielectric layer, and the organic semiconductor layer covers the gate dielectric layer, the source electrode, and the drain electrode so as to obtain a bottom contact organic thin film transistor.

According to the manufacturing method of the present invention, the present invention provides a method for manufacturing an N-type organic thin film transistor. In the step (D), a buffer layer is formed on the gate dielectric layer before forming the organic semiconductor layer.

According to the manufacturing method of the present invention, the present invention provides a method for manufacturing an organic floating gate electrode memory. In the step (D), a floating gate electrode is formed on the gate dielectric layer before forming the organic semiconductor layer. Furthermore, in the step (D): after forming the floating gate electrode, a dielectric layer is formed on the floating gate electrode; the dielectric layer disposes between the floating gate electrode and the semiconductor layer and covers the floating gate electrode.

According to the manufacturing method of the present invention, the present invention provides a method for manufacturing a metal-insulator-metal capacitor, comprising the following steps: (a) providing a substrate; (b) forming a first electrode on the substrate; (c) coating the substrate having the first electrode formed thereon with a bio-polymer solution to obtain a insulating layer on the substrate and the first electrode; and (d) forming a second electrode on the insulating layer.

According to the method for manufacturing a metal-insulator-metal capacitor, the step (c) comprises the flowing steps: (c1) providing a bio-polymer solution; (c2) coating the substrate having the first electrode formed thereon with the bio-polymer solution, or dipping the substrate having the first electrode formed thereon into the bio-polymer solution; and (c3) drying the bio-polymer solution which is coated on the substrate to obtain an insulating layer on the substrate and the first electrode.

According to the embodiment examples of the present invention, the electronic device and the method for manufacturing the same comprises: forming an electronic element, which includes a bio-polymer protein material, on a substrate having the first electrode formed thereon with a bio-polymer protein solution. Compared with the conventional method for forming a gate dielectric layer or an insulating layer by a sputtering method or vacuum vapor deposition method, the manufacturing method of the present invention can obtain a gate dielectric layer or an insulating layer via the solution process. Therefore, the manufacturing process is quite easy and the production cost is low. Moreover, the temperature of manufacturing process is lower than the conventional method so as to apply on large-area production. In addition, bio-polymer protein belongs to non-polluting environmental material, and it has a low production cost. For example, wool keratin is dissolved from wool waste, recycling the wool waste to apply on an electronic device, thus, the wool waste is assigned a high economic value again; collagen hydrolysate is hydrolyzed from animal by-products, making this material cheap and easily accessible; and gelatin has a much lower material cost, and it is also easily accessible commercially.

Furthermore, according to the embodiment examples of the present invention, compared with SiO₂ and Al₂O₃, bio-polymer protein matches well with pentacene. While using the bio-polymer protein material of the present invention as the material of the gate dielectric layer, and matching pentacene as the material of the P-type organic semiconductor layer, one can obtain a P-type OTFT with upraised field-effect mobility. For example, using wool keratin, collagen hydrolysate, and gelatin to form a gate dielectric layer in P-type OTFT separately, its hole field-effect mobility is about 3.5 cm²/V-sec, 8.5 cm²/V-sec, and 6.9 cm²/V-sec respectively. These results show wool keratin, collagen hydrolysate, and gelatin can match well with the material of the organic semiconductor layer, so the hole field-effect mobility can be increased greatly. Further, adding glycerol into the wool keratin can elevate the hole field-effect mobility to about 3.85 cm²/V-sec, assigning the wool keratin that is dissolved from wool waste a higher economic value.

In addition, compared with a conventional silicon-based floating gate electrode memory, the organic floating gate electrode memory including the bio-polymer of the present invention as the material of the dielectric layer has the properties of being flexible, lightweight, low priced, environmentally friendly, low operating voltage, etc. Therefore, the organic floating gate electrode memory can be integrated into organic electronic products to achieve the purposes of lighter weight, low production cost, and convenient carrying.

### BRIEF DESCRIPTION OF THE DRAWINGS

FIG. 1A is a perspective view of a conventional top contact OTFT;

FIG. 1B is a perspective view of a conventional bottom contact OTFT;

FIG. 2 is a perspective view of a conventional organic floating gate electrode memory;

FIG. 3 is a perspective view of a conventional MIM capacitor;

FIGS. 4A to 4D are cross-sectional views illustrating the process for manufacturing a top contact OTFT in Embodiment 1 of the present invention;

FIG. 5A is a curve showing the transfer characteristics of the OTFT of Embodiment 1 of the present invention; wherein ABS(I_{D}) represents the absolute value of the drain current (|I_{D}|);

FIG. 5B is a curve showing the output characteristics of the OTFT of Embodiment 1 of the present invention;

FIG. 6A is a curve showing the transfer characteristics of the OTFT of Embodiment 2 of the present invention; wherein ABS(I_{D}) represents the absolute value of the drain current (|I_{D}|);

FIG. 6B is a curve showing the output characteristics of the OTFT of Embodiment 2 of the present invention;

FIG. 7A is a curve showing the transfer characteristics of the OTFT of Embodiment 3 of the present invention; wherein ABS(I_{D}) represents the absolute value of the drain current (|I_{D}|);

FIG. 7B is a curve showing the output characteristics of the OTFT of Embodiment 3 of the present invention;

FIG. 8A is a curve showing the transfer characteristics of the OTFT of Embodiment 4 of the present invention; wherein ABS(I_{D}) represents the absolute value of the drain current (|I_{D}|);

FIG. 8B is a curve showing the output characteristics of the OTFT of Embodiment 4 of the present invention;

FIG. 9A is a curve showing the transfer characteristics of the OTFT of Embodiment 5 of the present invention; wherein ABS(I_{D}) represents the absolute value of the drain current (|I_{D}|) and ABS(I_{G}) represents the absolute value of the gate leakage current (|I_{G}|);

FIG. 9B is a curve showing the output characteristics of the OTFT of Embodiment 5 of the present invention;

FIG. 10A is a curve showing the transfer characteristics of the OTFT of Embodiment 6 of the present invention; wherein ABS(I_{D}) represents the absolute value of the drain current (I_{D}|) and SQRT(I_{D}) represents the square root of the drain current (I_{D}^{1/2});

FIG. 10B is a curve showing the output characteristics of the OTFT of Embodiment 6 of the present invention;

FIGS. 11A to 11C are cross-sectional views illustrating the process for manufacturing a bottom contact OTFT in Embodiment 7 of the present invention;

FIGS. 12A to 12D are cross-sectional views illustrating the process for manufacturing a top contact N-type OTFT in Embodiment 8 of the present invention;

FIG. 13A is a curve showing the transfer characteristics of the top contact N-type OTFT of gelatin and PTCDI-C8 of Embodiment 8 of the present invention; wherein ABS(I_{D}) represents the absolute value of the drain current (|I_{D}|), ABS(I_{G}) represents the absolute value of the gate leakage current, and SQRT(I_{D}) represents the square root of the drain current (I_{D}^{1/2});

FIG. 13B is a curve showing the output characteristics of the top contact N-type OTFT of gelatin and PTCDI-C8 of Embodiment 8 of the present invention;

FIG. 14A is a curve showing the transfer characteristics of the top contact N-type OTFT of wool keratin and PTCDI-C8 of Embodiment 8 of the present invention; wherein ABS(I_{D}) represents the absolute value of the drain current (|I_{D}|), ABS(I_{G}) represents the absolute value of the gate leakage current, and SQRT(I_{D}) represents the square root of the drain current (I_{D}^{1/2});

FIG. 14B is a curve showing the output characteristics of the top contact N-type OTFT of wool keratin and PTCDI-C8 of Embodiment 8 of the present invention;

FIG. 15A is a curve showing the transfer characteristics of the top contact N-type OTFT of collagen hydrolysate and fullerene of Embodiment 8 of the present invention; wherein ABS(I_{D}) represents the absolute value of the drain current (I_{D}|) and SQRT(I_{D}) represents the square root of the drain current (I_{D}^{1/2});

FIG. 15B is a curve showing the output characteristics of the top contact N-type OTFT of collagen hydrolysate and fullerene of Embodiment 8 of the present invention;

FIG. 16A is a curve showing the transfer characteristics of the top contact N-type OTFT of gelatin and fullerene of Embodiment 8 of the present invention; wherein ABS(I_{D}) represents the absolute value of the drain current (|I_{D}|) and SQRT(I_{D}) represents the square root of the drain current (I_{D}^{1/2});

FIG. 16B is a curve showing the output characteristics of the top contact N-type OTFT of gelatin and fullerene of Embodiment 8 of the present invention;

FIG. 17A is a curve showing the transfer characteristics of the top contact N-type OTFT of collagen hydrolysate and F₁₆CuPc of Embodiment 8 of the present invention; wherein ABS(I_{D}) represents the absolute value of the drain current (|I_{D}|), ABS(I_{G}) represents the absolute value of the gate leakage current, and SQRT(I_{D}) represents the square root of the drain current (I_{D}^{1/2});

FIG. 17B is a curve showing the output characteristics of the top contact N-type OTFT of collagen hydrolysate and F₁₆CuPc of Embodiment 8 of the present invention;

FIG. 18A is a curve showing the transfer characteristics of the top contact N-type OTFT of gelatin and F₁₆CuPc of Embodiment 8 of the present invention; wherein ABS(I_{D}) represents the absolute value of the drain current (|I_{D}|), ABS(I_{G}) represents the absolute value of the gate leakage current, and SQRT(I_{D}) represents the square root of the drain current (I_{D}^{1/2});

FIG. 18B is a curve showing the output characteristics of the top contact N-type OTFT of gelatin and F₁₆CuPc of Embodiment 8 of the present invention;

FIGS. 19A to 19D are cross-sectional views illustrating the process for manufacturing a bottom contact N-type OTFT in Embodiment 9 of the present invention;

FIG. 20 is a perspective view of a top contact organic floating gate electrode memory in Embodiment 10 of the present invention;

FIG. 21 is a curve showing the transfer characteristics of the top contact organic floating gate electrode memory of collagen hydrolysate of Embodiment 10 of the present invention; wherein ABS(I_{D}) represents the absolute value of the drain current (|I_{D}|);

FIG. 22 is a curve showing the transfer characteristics of the top contact organic floating gate electrode memory of gelatin of Embodiment 10 of the present invention; wherein ABS(I_{D}) represents the absolute value of the drain current (|I_{D}|);

FIG. 23 is a perspective view of a bottom contact organic floating gate electrode memory in Embodiment 11 of the present invention;

FIGS. 24A to 24C are cross-sectional views illustrating the process for manufacturing a MIM capacitor in Embodiment 12 of the present invention;

FIG. 25 is a curve showing the capacitance-voltage characteristics of the MIM capacitor of collagen hydrolysate of Embodiment 12 of the present invention;

FIG. 26 is a curve showing the capacitance-voltage characteristics of the MIM capacitor of wool keratin of Embodiment 12 of the present invention; and

FIG. 27 is a curve showing the capacitance-voltage characteristics of the MIM capacitor of gelatin of Embodiment 12 of the present invention.

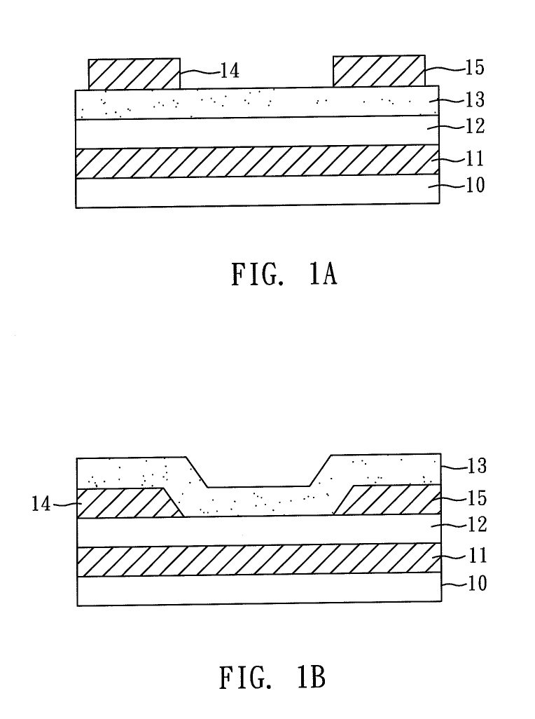

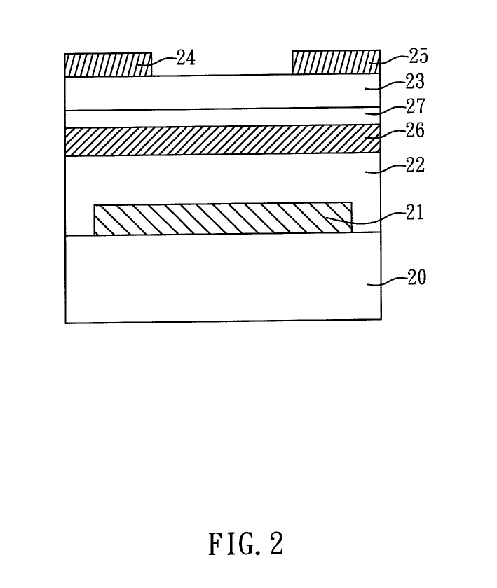

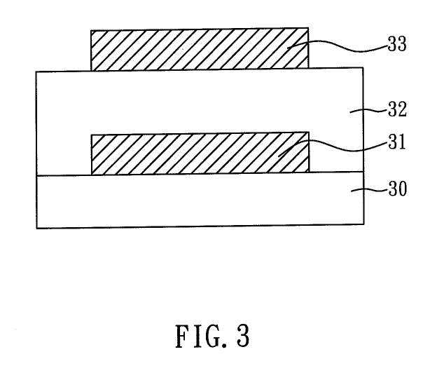

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

### Preparation Embodiment 1

### Preparation of a Wool Keratin Solution

First, the wool was cleaned with Clearwater, and then the cleaned wool was soaked in a the solution composed of ethanol and acetone. Second, the ethanol and acetone were washed out by deionized water, and the dried wool was soaked in a the solution composed of thioethyl alcohol, urea, and sodiumdodecylsulfate (SDS) to extract the wool keratin. Finally, the solution having the wool keratin dissolved therein was dialysed by a dialysis membrane to obtain a wool keratin solution.

### Preparation Embodiment 2

### Preparation of a Collagen Hydrolysate Solution

The collagen hydrolysate power extracted from pigskin was purchased from Ken Le Ad Development CO., LTD., and then was dissolved in deionized water to obtain a collagen hydrolysate solution with about 2-4% concentration.

### Preparation Embodiment 3

### Preparation of a Gelatin Solution

The gelatin power was purchased from Sigma-Aldrich, and then was dissolved in deionized water to obtain a gelatin solution with various concentrations.

### Preparation Embodiment 4

### Preparation of a Whey Protein Solution

The whey power was purchased from NOW Foods Bloomingdale (Ill., USA), and then was dissolved in deionized water to obtain a whey protein solution with various concentrations.

### Preparation Embodiment 5

### Preparation of a Hydroxypropyl Methylcellulose Solution

The hydroxypropyl methylcellulose power was purchased from Sigma-Aldrich Co. LLC, and then was dissolved in deionized water to obtain a gelatin solution with various concentrations.

### Example 1

### Top Contact OTFT Including Wool Keratin

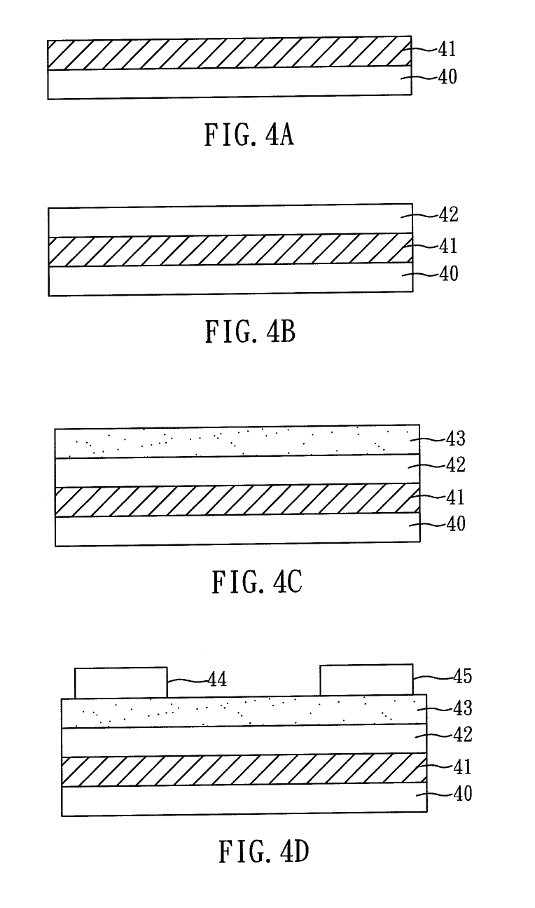

FIGS. 4A to 4D are illustrating the process for manufacturing a top contact OTFT including wool keratin.

As shown in FIG. 4A, a substrate 40 was provided, and the substrate 40 was cleaned by deionized water through a sonication process. In the present embodiment, the substrate 30 was a transparent plastic substrate made of PET. Next, the substrate 40 was placed inside a vacuum chamber (not shown in the figure), and a metal was evaporated onto the substrate 40 by using a mask (not shown in the figure) to form a patterned metal layer, which was used as a gate electrode 41. In the present example, the metal used in the gate electrode 41 was Au, and the thickness of the gate electrode 41 was about 65 nm. In addition, the condition of the evaporation process for forming the gate electrode 41 is listed below: Pressure: 5×10⁻⁶ torr, Evaporation rate: 1 Å/s.

Then, the substrate 40 having the gate electrode 41 formed thereon was dipped into the wool keratin solution for 15 mins to coat the substrate 40 having the gate electrode 41 with the wool keratin solution. After the coating process, the substrate 40 coated with the wool keratin solution was dried at 60° C. to form a wool keratin film, and the wool keratin film was used as a gate dielectric layer 42, as shown in FIG. 4B. In the present embodiment, the gate dielectric layer 42 formed by the wool keratin film has a thickness of 400 nm.

In addition, the coating process and the drying process can be performed several times to form a wool keratin film with multi-layered structure.

As shown in FIG. 4C, through a heat evaporation process, pentacene was deposited on the gate dielectric layer 42 at room temperature by use of a shadow metal mask to form an organic semiconductor layer 43. In the present embodiment, the thickness of the organic semiconductor layer 43 is about 60 nm. In addition, the condition of the heat evaporation process for forming the organic semiconductor layer 43 is listed below: Pressure: 2×10⁻⁶ torr, Evaporation rate: 0.3 Å/s.

Finally, the same evaporation process and condition for forming the gate electrode 41 was performed to form a patterned metal layer, which was used as a source electrode 44 and a drain electrode 45, on the organic semiconductor layer 43 by using another mask (not shown in the figure), as shown in FIG. 4D. In the present embodiment, the material of the source electrode 44 and the drain electrode 45 was Au, and the thickness of the source electrode 44 and the drain electrode 45 was about 65 nm.

As shown in FIG. 4D, after the aforementioned process, a top contact OTFT of the present embodiment was obtained, which comprises: the substrate 40; the gate electrode 41 disposed on the substrate 40; the gate dielectric layer 42 disposed on the substrate 40 and covering the gate electrode 41, wherein the gate dielectric layer 42 comprises wool keratin; the organic semiconductor layer 43 covering the entire surface of the gate dielectric layer 42; and the source electrode 44 and the drain electrode 45, respectively disposed on the organic semiconductor layer 43.

### Example 2

### Top Contact OTFT Including Wool Keratin

The processes, procedures, and conditions were the same as described in Example 1, except that the material of the wool keratin solution obtained in Example 1 and glycerol was added together to form the film of the gate dielectric layer 42.

### Example 3

### Top Contact OTFT Including Collagen Hydrolysate

The processes, procedures, and conditions were the same as described in Example 1, except that the material of the collagen hydrolysate solution obtained in Example 2 was used to form the film of the gate dielectric layer 42.

### Example 4

### Top Contact OTFT Including Gelatin

The processes, procedures, and conditions were the same as described in Example 1, except that the material of the gelatin solution obtained in Example 3 was used to form the film of the gate dielectric layer 42.

### Example 5

### Top Contact OTFT Including Whey Protein

The processes, procedures, and conditions were the same as described in Example 1, except that the material of the whey protein solution obtained in Example 4 was used to form the film of the gate dielectric layer 42.

### Example 6

### Top Contact OTFT Including Hydroxypropyl Methylcellulose

The processes, procedures, and conditions were the same as described in Example 1, except that the material of the hydroxypropyl methylcellulose solution obtained in Example 5 was used to form the film of the gate dielectric layer 42.

### Evaluation of the Characteristics of the OTFT

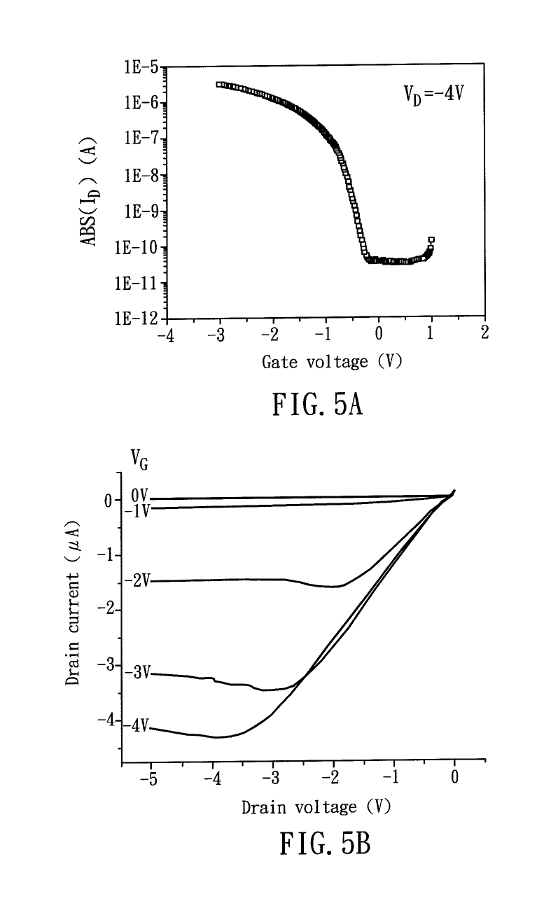

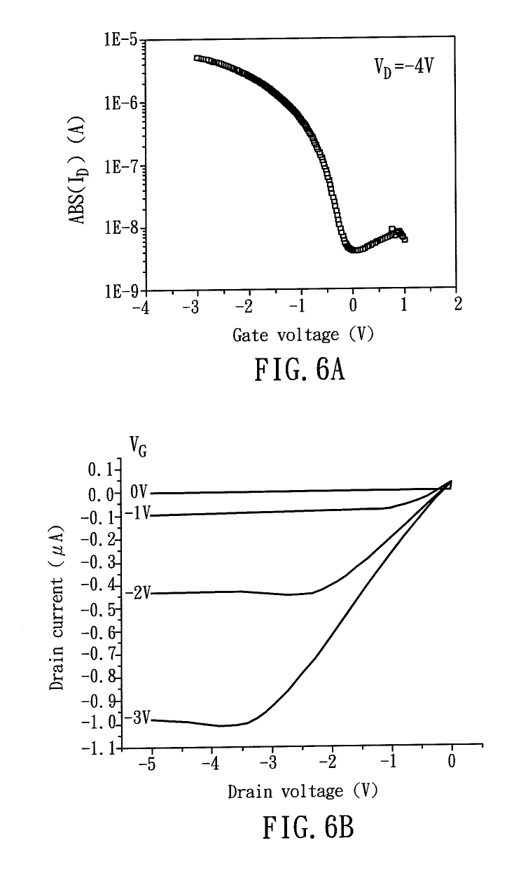

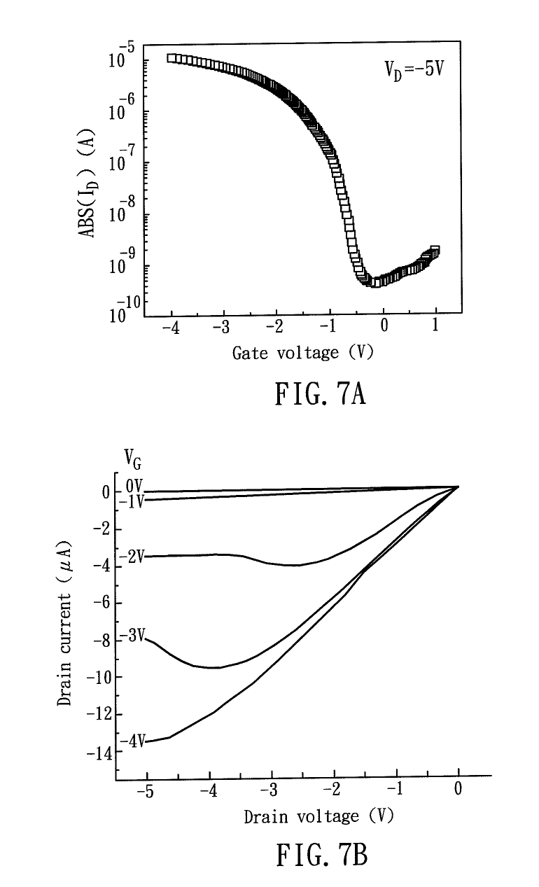

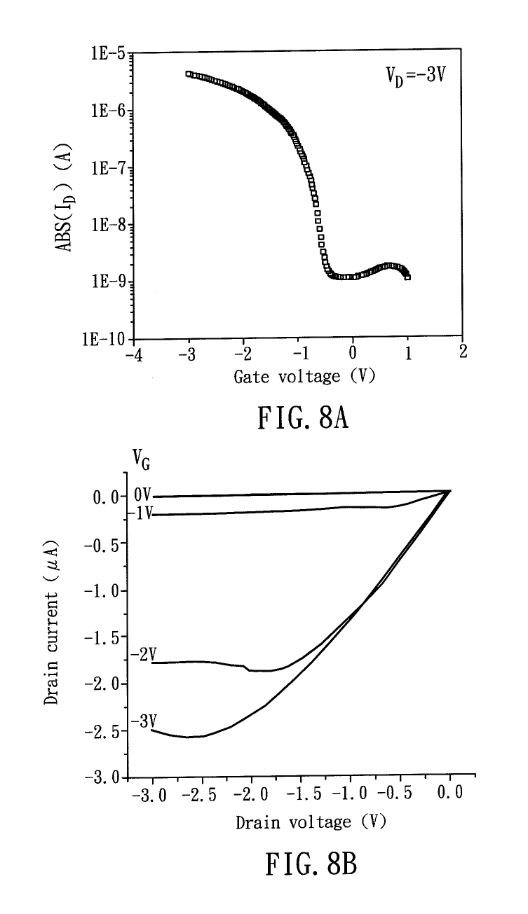

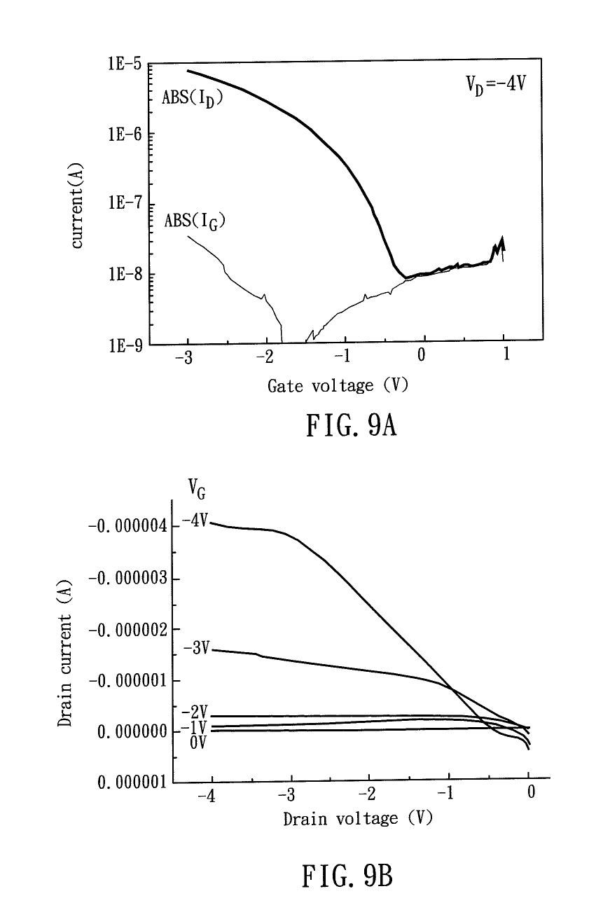

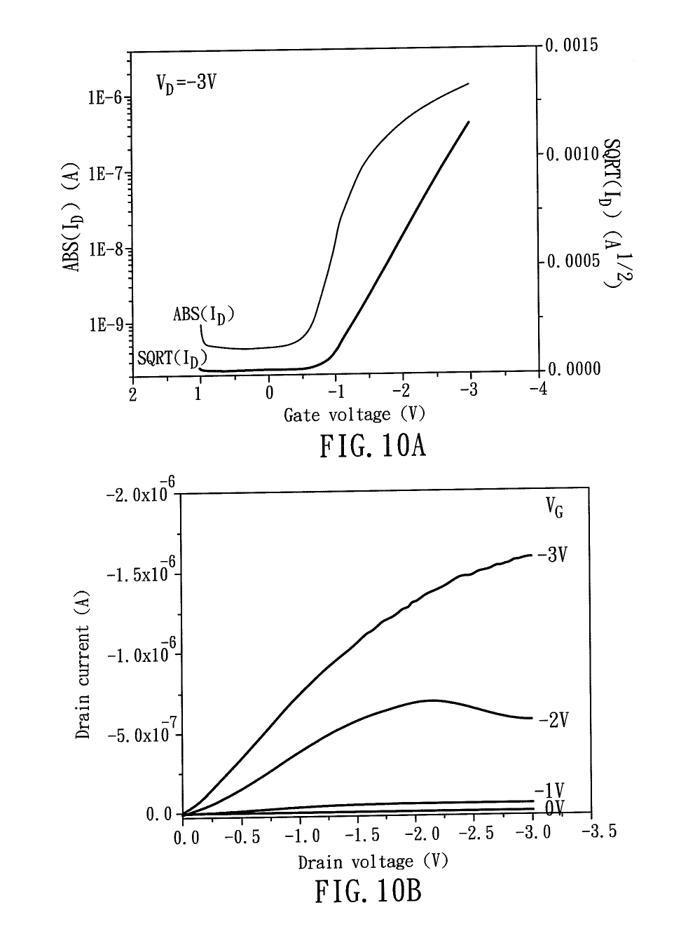

A current-voltage test was performed on the P-type top contact OTFT of Examples 1 to 6. The results of the transfer characteristics of the OTFT are shown in FIGS. 5A, 6A, 7A, 8A, 9A, and 10A respectively, and the results of the output characteristics under different gate voltages (V_{G}) are shown in FIGS. 5B, 6B, 7B, 8B, 9B, and 10B respectively. In FIGS. 5A, 6A, 7A, 8A, 9A and 10A, ABS(I_{D}) represents the absolute value of the drain current (|I_{D}|), ABS(I_{G}) represents the absolute value of the gate leakage current, and SQRT(I_{D}) represents the square root of the drain current (I_{D}^{1/2}). The output characteristics in FIG. 5B, the V_{G} from top to bottom are 0, −1, −2, −3, and −4 V respectively. The output characteristics in FIG. 6B, the V_{G} from top to bottom are 0, −1, −2, and −3 V respectively. The output characteristics in FIG. 7B, the V_{G} from top to bottom are 0, −1, −2, −3, and −4 V respectively. The output characteristics in FIG. 8B, the V_{G} from top to bottom are 0, −1, −2, and −3 V respectively. The output characteristics in FIG. 9B, the V_{G} from top to bottom are −4, −3, −2, −1, and 0 V respectively. The output characteristics in FIG. 10B, the V_{G} from top to bottom are −3, −2, −1, and 0 V respectively.

The current on-to-off ratio (I_{ON/OFF}), the subthreshold swing (S.S.), the hole field-effect mobility and the threshold voltage (V_{TH}) are listed in the following Table 1.

TABLE 1

| | Example 1 | Example 2 | Example 3 | Example 4 | Example 5 | Example 6 |
|---|---|---|---|---|---|---|
| Channel width | 600 | | | | | |
| (μm) | | | | | | |
| Channel length | 50 | | | | | |
| (μm) | | | | | | |
| Thickness of the | 600 | | | | | |
| organic | | | | | | |
| semiconductor | | | | | | |
| layer (nm) | | | | | | |
| On-to-off ratio | 9 × 10⁴ | 1.2 × 10³ | 2.6 × 10⁴ | 3.8 × 10³ | 9 × 10² | 8 × 10² |
| (I_{ON}/I_{OFF}) | | | | | | |
| Subthreshold swing | −0.155 | −0.158 | −0.162 | −0.240 | −0.173 | −0.3 |
| (V/decade) | | | | | | |
| hole field-effect | 3.50 | 3.85 | 8.5 | 6.87 | | 2.6 |
| mobility | | | | | | |
| (cm²/V-sec) | | | | | | |
| threshold voltage | −0.504 | −0.216 | −0.78 | −0.56 | −0.36 | −0.7 |
| (Vₜₕ) | | | | | | |

According to the results shown in FIG. 5A to FIG. 10B and Table 1, the field-effect mobility of the gate dielectric layer made of the wool keratin (Example 1), wool keratin combined glycerol (Example 2), collagen hydrolysate (Example 3), gelatin (Example 4) and hydroxypropyl methylcellulose (Example 6) are 3.50 cm²/V-sec, 3.85 cm²/V-sec, 8.5 cm²/V-sec, 6.87 cm²/V-sec, 6 cm²/V-sec, and 2.6 cm²/V-sec respectively. Accordingly, the gate dielectric layers including collagen hydrolysate (Example 3) and gelatin (Example 4) show better efficiency. In addition, by adding glycerol into the wool keratin, the hole field-effect mobility is higher than using the wool keratin only.

### Example 7

### Bottom Contact OTFT

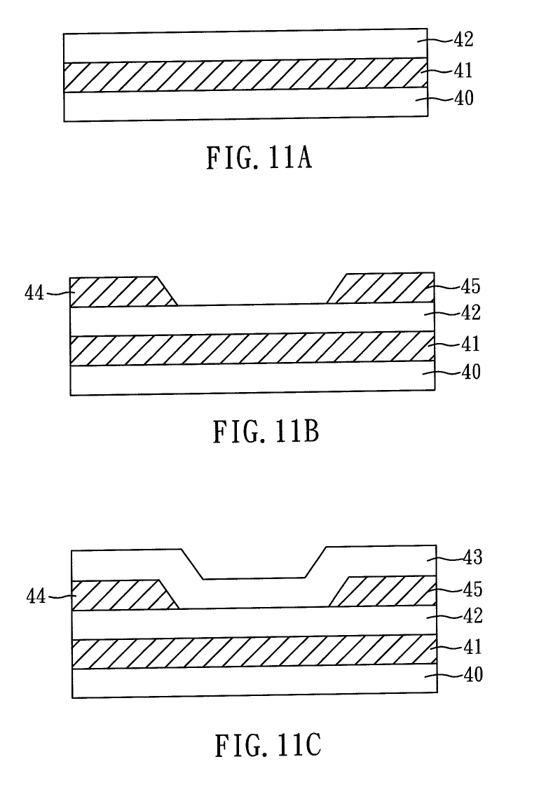

FIGS. 11A to 11D illustrate the process for manufacturing a bottom contact OTFT.

As shown in FIG. 11A, a substrate 40 was provided, and a gate electrode 41 and a gate dielectric layer 42 were formed on the substrate 40 sequentially. In the present Example, the material of the substrate 40 and gate electrode 41 and the manufacturing method were the same as described in Example 1, and the material of the gate dielectric layer 42 is selected from wool keratin, wool keratin combined with glycerol, collagen hydrolysate, gelatin, whey protein or hydroxypropyl methylcellulose. In the present Example, the thickness of the gate electrode 41 is about 65 nm, and the thickness of the gate dielectric layer is about 400 nm.

Then, the same manufacturing process and condition as described in Example 1 for forming the gate electrode was used, and to form a patterned metal layer on the gate dielectric layer 42. The patterned metal layer was used as a source electrode 44 and a drain electrode 45, as shown in FIG. 11B. In the present Example, the material of the source electrode 44 and the drain electrode 45 was Au, and the thickness of the source electrode 44 and the drain electrode 45 was about 65 nm.

Finally, the same manufacturing process and condition as described in Example 1 for forming the organic semiconductor layer was used, and to form an organic semiconductor layer 43 on the gate dielectric layer 42, source electrode 44, and drain electrode 45, as shown in FIG. 11C. In the present Example, the material of the organic semiconductor layer 43 was pentacene, and the thickness of the organic semiconductor layer 43 was about 60 nm.

As shown in FIG. 11C, after the aforementioned process, a bottom contact OTFT of the present embodiment was obtained, which comprises: the substrate 40; the gate electrode 41 disposed on the substrate 40; the gate dielectric layer 42 disposed on the substrate 40 and covering the gate electrode 41, wherein the gate dielectric layer 42 comprises a bio-polymer; the source electrode 44 and the drain electrode 45 disposed on the gate dielectric layer 42; and the organic semiconductor layer 43 covering the gate dielectric layer 42, the source electrode 44 and the drain electrode 45.

### Example 8

### Top Contact N-Type OTFT

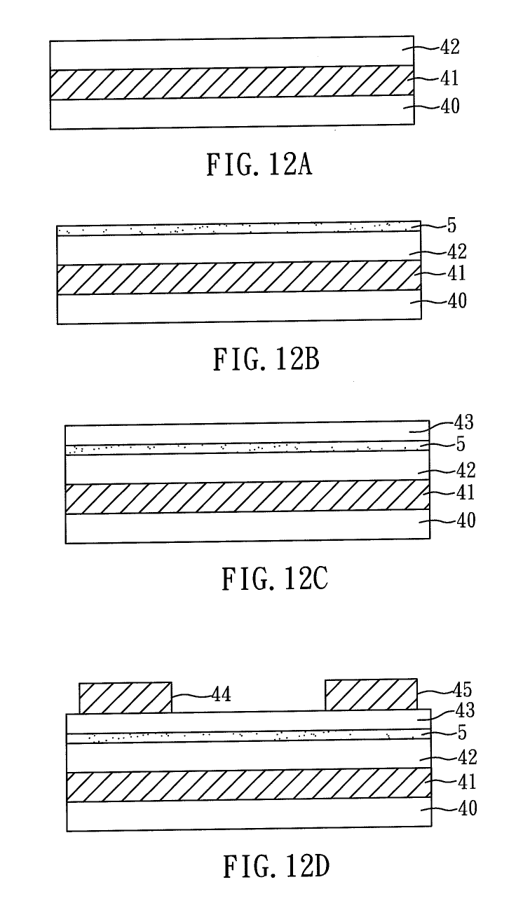

FIGS. 12A to 12D illustrate the process for manufacturing a top contact N-type OTFT.

As shown in FIG. 12A, a substrate 40 was provided, and a gate electrode 41 and a gate dielectric layer 42 were formed on the substrate 40 sequentially. In the present Example, the material of the substrate 40 and gate electrode 41 and the manufacturing method were the same as described in Example 1, and the material of the gate dielectric layer 42 is selected from wool keratin, wool keratin combined glycerol, collagen hydrolysate, gelatin, whey protein or hydroxypropyl methylcellulose.

As shown in FIG. 12B, through a heat evaporation process, pentacene was deposited on the gate dielectric layer 42 at room temperature by use of a shadow metal mask to form a buffer layer 5. In the present Example, the thickness of the buffer layer 5 is about 3 nm. In addition, the condition of the heat evaporation process for forming the buffer layer 5 is listed below: Pressure: 1×10⁻⁶ torr, Evaporation rate: 0.03 nm/s.

Then, the same manufacturing process and condition as described in Example 1 for forming the organic semiconductor layer was used, and to form an organic semiconductor layer 43 on the buffer layer 5, as shown in FIG. 12C.

Finally, the same manufacturing process and condition as described in the Example 1 for forming the gate electrode was used, and to form a patterned metal layer on the organic semiconductor layer 43. The patterned metal layer was used as a source electrode 44 and a drain electrode 45, as shown in FIG. 12D.

As shown in FIG. 12D, after the aforementioned process, a top contact N-type OTFT of the present embodiment was obtained, which comprises: the substrate 40; the gate electrode 41 disposed on the substrate 40; the gate dielectric layer 42 disposed on the substrate 40 and covering the gate electrode 41, wherein the gate dielectric layer 42 comprises a bio-polymer; the buffer layer 5 covering the entire surface of the gate dielectric layer 42; the organic semiconductor layer 43 covering the entire surface of the buffer layer 5; and the source electrode 44 and the drain electrode 45, respectively disposed on the organic semiconductor layer 43.

### Evaluation the Characteristics of the N-Type OTFT

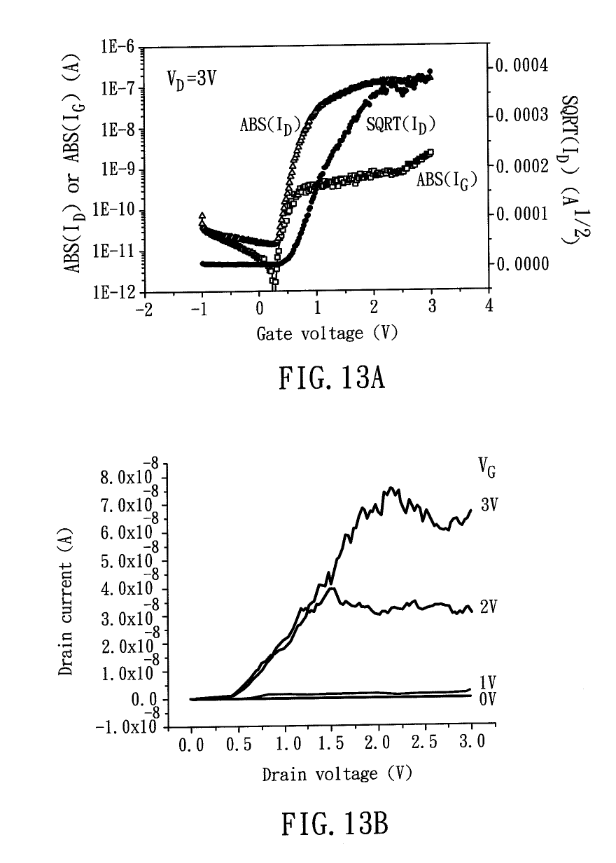

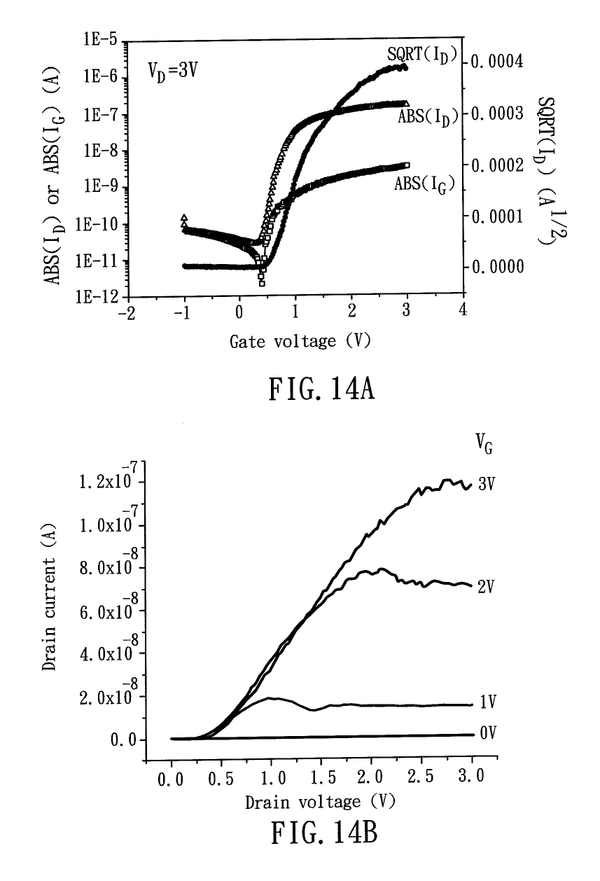

A transfer characteristics test was performed on the N-type top contact OTFT of which gelatin and wool keratin were used to obtain the gate dielectric layer 42 and PTCDI-C8 was used to obtain the organic semiconductor layer 43 (the steps of forming the buffer layer 5 were omitted). The results of the transfer characteristics of the OTFT are shown in FIGS. 13A and 14A respectively, and the results of the output characteristics are shown in FIGS. 13B and 14B respectively. In FIGS. 13A and 14A, ABS(I_{D}) represents the absolute value of the drain current (|I_{D}|)ABS(I_{G}) represents the absolute value of the leakage current (|I_{G}|), and SQRT(I_{D}) represents the square root of the drain current (I_{D}^{1/2}). The output characteristics in FIGS. 13B and 14B, both of the V_{G} from top to bottom are 3, 2, 1, and 0V respectively. The current on-to-off ratio (I_{ON/OFF}), the subthreshold swing (S.S.), the hole field-effect mobility and the threshold voltage (V_{TH}) are listed in the following Table 2.

TABLE 2

| | Gelatin | Wool keratin |
|---|---|---|
| Current on-to-off ratio (I_{ON}/I_{OFF}) | 1.0 × 10⁴ | 4.5 × 10³ |
| Subthreshold swing (mV/decade) | 0.152 | 0.145 |
| Hole field-effect mobility (cm²/V-sec) | 1.70 | 0.55 |
| Threshold voltage (Vₜₕ) | 0.46 | 0.55 |
| Slope | 0.000292 | 0.000388 |

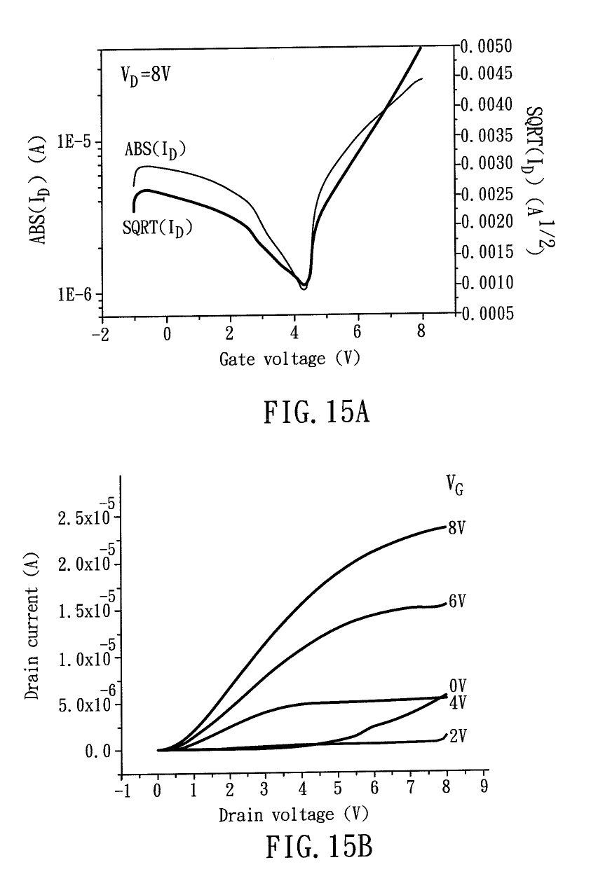

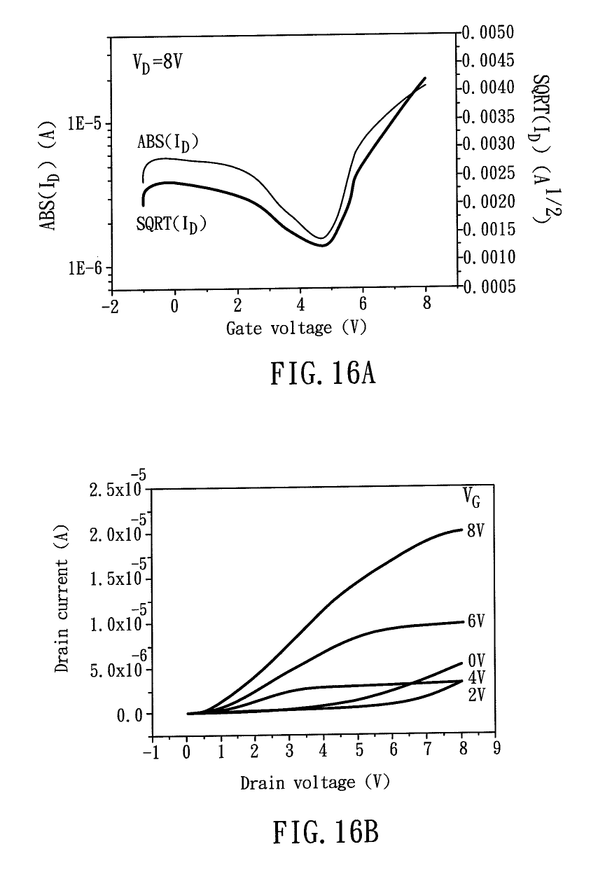

Another transfer characteristics test was performed on the N-type top contact OTFT of which collagen hydrolysate and gelatin were used to obtain the gate dielectric layer 42 and fullerene was used to obtain the organic semiconductor layer 43. The results of the transfer characteristics of the OTFT are shown in FIGS. 15A and 16A respectively, and the results of the output characteristics are shown in FIGS. 15B and 16B respectively. In FIGS. 15A and 16A, the definition of ABS(I_{D}) and SQRT(I_{D}) are the same as described in Example 6. The output characteristics in FIGS. 15B and 16B, both of the V_{G} from top to bottom (judges by the I_{D} value while V_{D}=8) are 8, 6, 0, 4, and 2V respectively. The electron field-effect mobility of the OTFT that used collagen hydrolysate and gelatin to form the gate dielectric layer are 5.3 cm²/V-sec and 4 cm²/V-sec respectively.

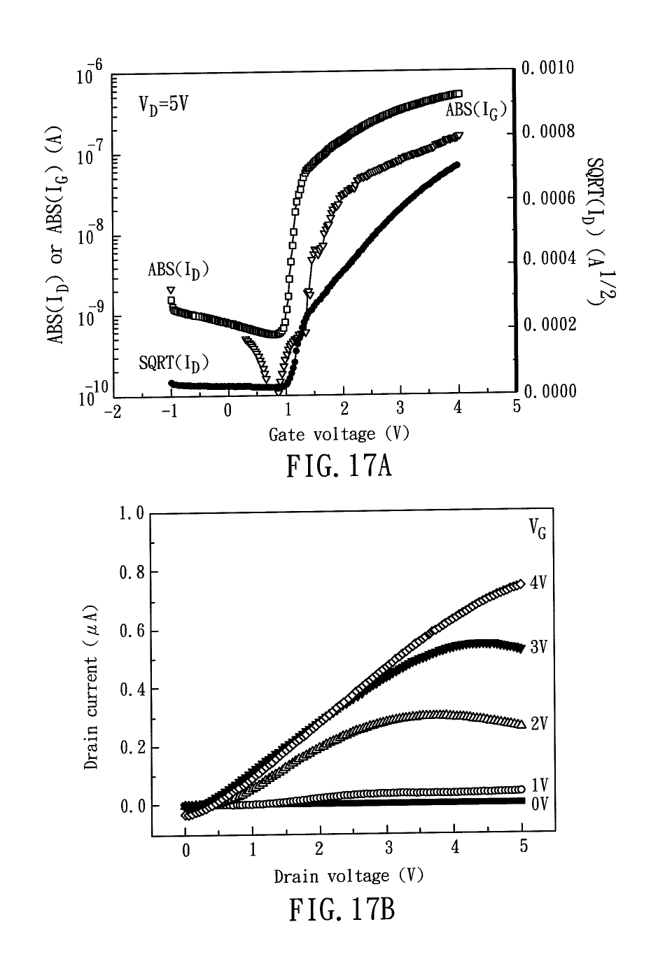

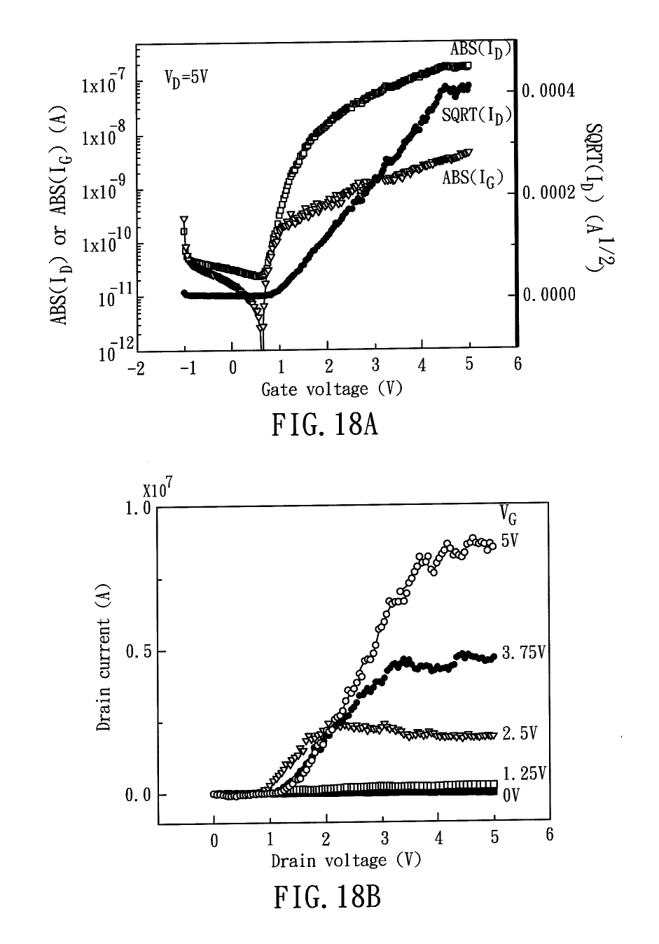

Still another transfer characteristics test was performed on the N-type top contact OTFT of which collagen hydrolysate and gelatin were used to obtain the gate dielectric layer 42 and F₁₆CuPc (COPPER1,2,3,4,8,9,10,11,15,16,17,18,22,23,24,25-HEXADECAFLUO RO-PHTHALOCYANINE, SIGMA-ALDRICH 14916871) was used to obtain the organic semiconductor layer 43 (the steps of forming the buffer layer 5 were omitted). The results of the transfer characteristics of the OTFT are shown in FIGS. 17A and 18A respectively. In FIGS. 17A and 18A, ABS(I_{D}) represents the absolute value of the drain current (|I_{D}|), ABS(I_{G}) represents the absolute value of the gate leakage current, (|I_{G}|) and SQRT(I_{D}) represents the square root of the drain current (|_{D}^{1/2}). The results of the output characteristics are shown in FIGS. 17B and 18B respectively. The output characteristics in FIG. 17B, the V_{G} from top to bottom are 4, 3, 2, 1, and 0V. The output characteristics in FIG. 18B, the V_{G} from top to bottom are 5, 3.75, 2.5, 1.25, and 0V. The electron field-effect mobility of the OTFT that was used collagen hydrolysate and gelatin to form the gate dielectric layer are 0.23 cm²/V-sec and 0.35 cm²/V-sec respectively.

### Example 9

### Bottom Contact N-Type OTFT

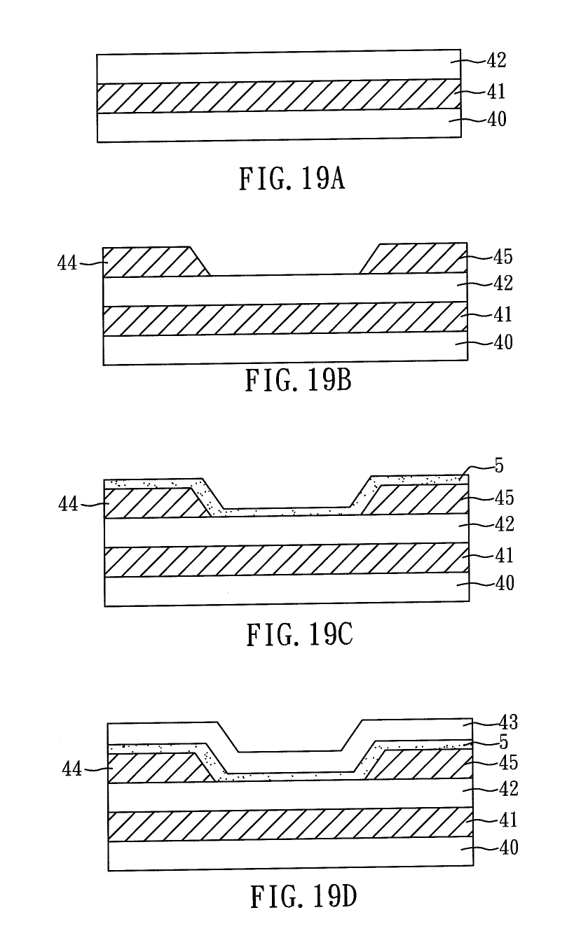

FIGS. 19A to 19D illustrate the process for manufacturing a bottom contact N-type OTFT.

As shown in FIG. 19A, a substrate 40 was provided, and a gate electrode 41 and a gate dielectric layer 42 were formed on the substrate 40 sequentially. In the present Example, the material of the substrate 40 and gate electrode 41 and the manufacturing method were the same as described in Example 1, and the material of the gate dielectric layer 42 is selected from wool keratin, wool keratin combined glycerol, collagen hydrolysate, gelatin, whey protein or hydroxypropyl methylcellulose.

As shown in FIG. 19B, the same manufacturing process and condition as described in Example 1 for forming the gate electrode was used, and to form a patterned metal layer on the gate dielectric layer 42. The patterned metal layer was used as a source electrode 44 and a drain electrode 45.

Then, pentacene was deposited on the gate dielectric layer 42, the source electrode 44, and the drain electrode 45 to form a buffer layer 5, as shown in FIG. 19C.

Finally, the same manufacturing process and condition as described in Example 1 for forming the organic semiconductor layer was used, and to form an organic semiconductor layer 43 on the buffer layer 5, as shown in FIG. 19D.

As shown in FIG. 19D, after the aforementioned process, a bottom contact N-type OTFT of the present embodiment was obtained, which comprises: the substrate 40; the gate electrode 41 disposed on the substrate 40; the gate dielectric layer 42 disposed on the substrate 40 and covering the gate electrode 41, wherein the gate dielectric layer 42 comprises a bio-polymer; the source electrode 44 and the drain electrode 45 disposed on the gate dielectric layer 42; the buffer layer 5 covering the gate dielectric layer 42, the source electrode 44, and the drain electrode 45; and the organic semiconductor layer 43 covering the entire surface of the buffer layer 5.

### Example 10

### Top Contact Organic Floating Gate Electrode Memory

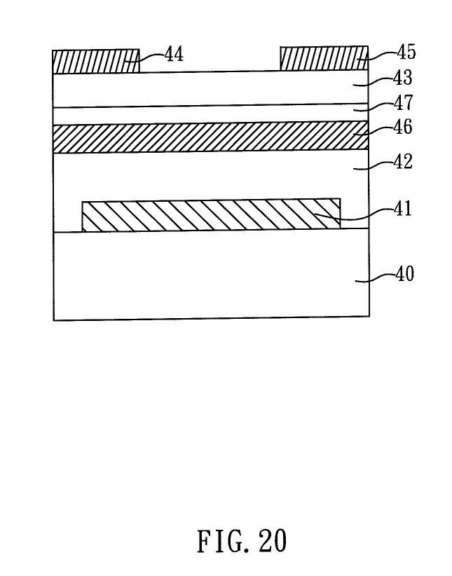

As shown in FIG. 20, a gate electrode 41, a gate dielectric layer 42, an organic semiconductor layer 43, a source electrode 44, and a drain electrode 45 were formed on the substrate 40 sequentially. In the present Example, a metal (Au) was evaporated onto the gate dielectric layer 42 by using a mask (not shown in the figure) to form a patterned metal layer, which was used as a floating gate 46. Then, the same manufacturing process and condition as described in the Example 1 for forming the gate dielectric layer 42 was used, and to form a bio-polymer film on the floating gate 46. The patterned metal layer was used as a dielectric layer 47.

Accordingly, the top contact organic floating gate electrode memory of the present embodiment comprises: the substrate 40; the gate electrode 41 disposed on the substrate 40; the gate dielectric layer 42 disposed on the substrate 40 and covering the gate electrode 41, wherein the gate dielectric layer 42 comprises a bio-polymer; the floating gate 46 covering the gate dielectric layer 42; the dielectric layer 47 covering the floating gate 46; the organic semiconductor layer 43 covering the dielectric layer 47; and the source electrode 44 and the drain electrode 45 disposed on the organic semiconductor layer 43.

### Evaluation of the Characteristics

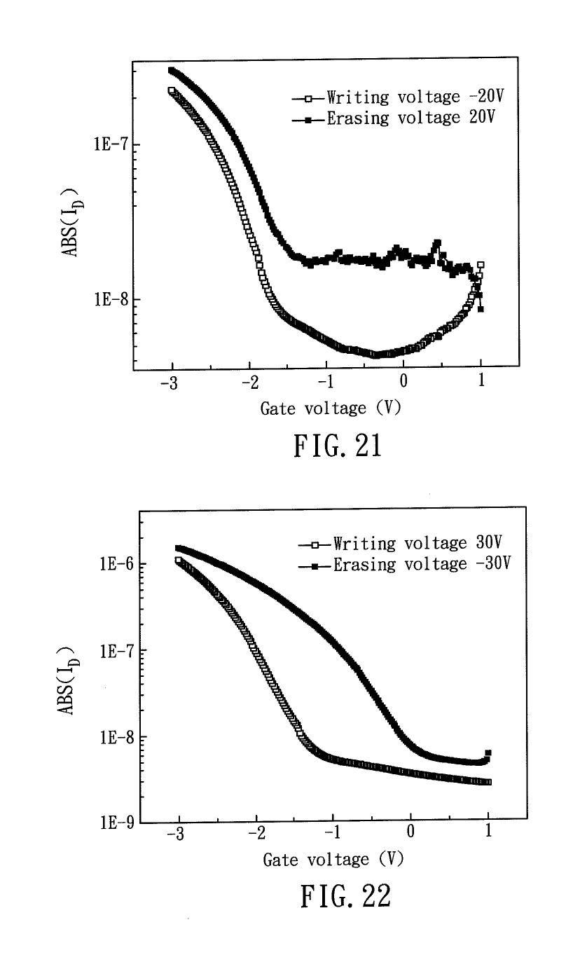

A transfer characteristic test was performed on the top contact organic floating gate electrode memory of which collagen hydrolysate and gelatin were used to obtain the dielectric layer 47. The results of the transfer characteristics are shown in FIGS. 21 and 22, and ABS(I_{D}) represents the absolute value of the drain current (|I_{D}|).

### Example 11

### Bottom Contact Organic Floating Gate Electrode Memory

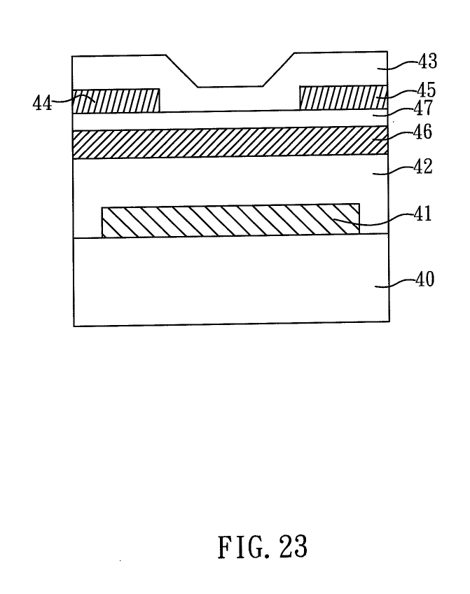

As shown in FIG. 23, a gate electrode 41, a gate dielectric layer 42, a source electrode 44, a drain electrode 45, and an organic semiconductor layer 43, were formed on the substrate 40 sequentially. In the present Example, a metal (Au) was evaporated onto the gate dielectric layer 42 by using a mask (not shown in the figure) to form a patterned metal layer, which was used as a floating gate 46. Then, the same manufacturing process and condition as described in Example 1 for forming the gate dielectric layer 42 was used, and to form a bio-polymer film on the floating gate 46. The bio-polymer film was used as a dielectric layer 47.

Accordingly, the top contact organic floating gate electrode memory of the present embodiment comprises: the substrate 40; the gate electrode 41 disposed on the substrate 40; the gate dielectric layer 42 disposed on the substrate 40 and covering the gate electrode 41, wherein the gate dielectric layer 42 comprises a bio-polymer; the floating gate 46 covering the gate dielectric layer 42; the dielectric layer 47 covering the floating gate 46; the source electrode 44 and the drain electrode 45 disposed on the dielectric layer 47; and the organic semiconductor layer 43 covering the dielectric layer 47, the source electrode 44, and the drain electrode 45.

### Example 12

### MIM Capacitor

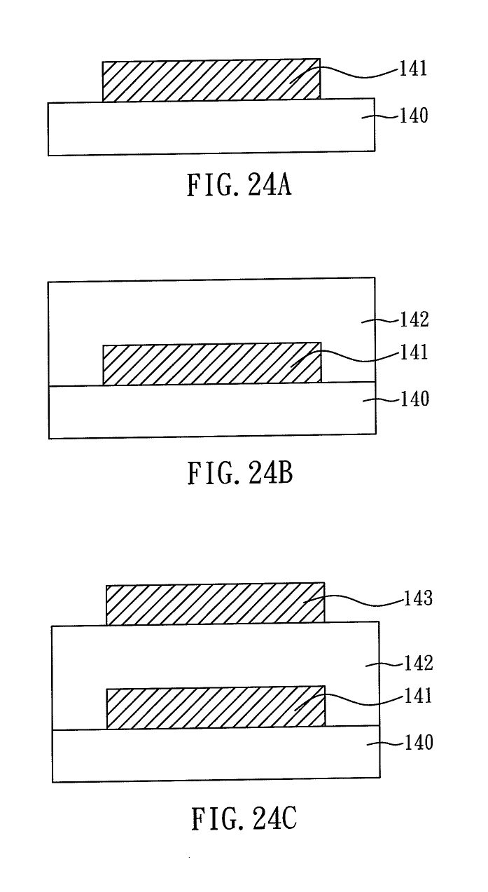

FIGS. 24A to 24C illustrate the process for manufacturing a MIM capacitor.

As shown in FIG. 24A, a substrate 140 was provided, and a first electrode 141 was formed on the substrate 140. In the present Example, the same manufacturing process and condition as described in the Example 1 for forming the gate electrode 41 was used to form the first electrode 141; the substrate 140 is a plastic substrate and the material of the first electrode 141 is Au.

Then, the same manufacturing process and condition as described in Example 1 for forming the gate dielectric layer 42 was used, and to form a bio-polymer film covering the first electrode 141. The bio-polymer film was used as an insulating layer 142, as shown in FIG. 24B.

Finally, the substrate 140 was placed inside a vacuum chamber (not shown in the figure) under 5×10⁻⁶ torr for evaporation to form a second electrode 143, as shown in FIG. 24C.

As shown in FIG. 24C, after the aforementioned process, a MIM capacitor of the present embodiment was obtained, which comprises: the substrate 140; the first electrode 141 disposed on the substrate 140; the insulating layer 142 disposed on the substrate 140 and covering the first electrode 141, wherein the insulating layer 142 comprises a bio-polymer; and the second electrode 143 disposed on the insulating layer.

### Evaluation of the Characteristics

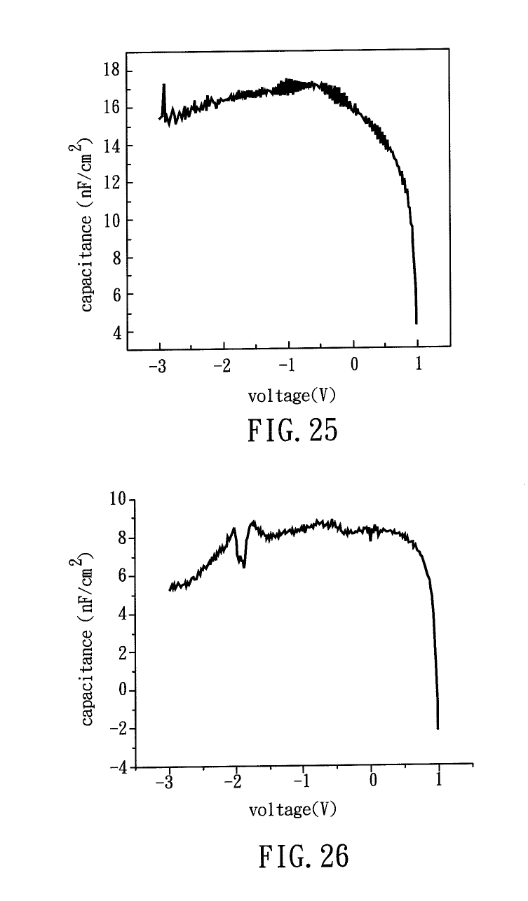

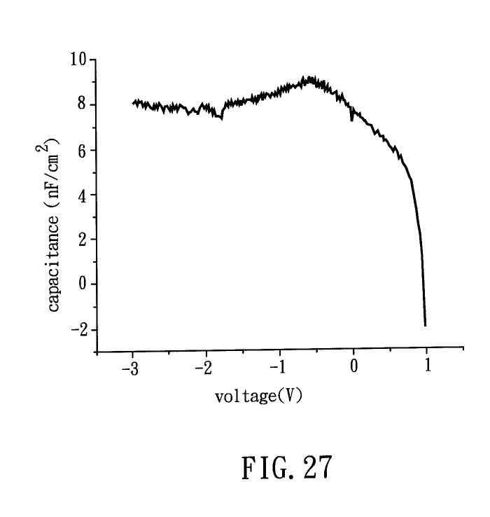

A dielectric property test was performed on the MIM capacitor of which collagen hydrolysate, wool keratin, and gelatin were used to obtain the insulating layer 142. The results of the capacitance (nF/cm²)-voltage property are shown in FIGS. 25, 26, and 27. These experimental results prove that the bio-polymer material is an excellent dielectric material.

Although the present invention has been explained in relation to its preferred embodiment, it is to be understood that many other possible modifications and variations can be made without departing from the spirit and scope of the invention as hereinafter claimed.

What is claimed is:

1. An electronic device including a bio-polymer material, comprising:
a substrate;
a first electrode disposed on the substrate;
a bio-polymer layer disposed on the first electrode, wherein the material of the bio-polymer is selected from a group consisting of wool keratin, collagen hydrolysate, gelatin, whey protein and hydroxypropyl methylcellulose; and
a second electrode disposed over the biopolymer material layer.

2. The electronic device including a bio-polymer material as claimed in claim 1, wherein the bio-polymer layer has a single-layered structure or a multi-layered structure.

3. The electronic device including a bio-polymer material as claimed in claim 1, wherein the substrate is a plastic substrate, a glass substrate, a quartz substrate, a silicon substrate, or a paper substrate.

4. The electronic device including a bio-polymer material as claimed in claim 1, wherein the material of the electrode is selected from a group consisting of Al, Cu, Cr, Ag, Pt, Au, ZnO, and ITO.

5. The electronic device including a bio-polymer material as claimed in claim 1, wherein the bio-polymer material layer is a gate dielectric layer; the first electrode is a gate electrode disposed between the substrate and the gate dielectric layer, and the gate dielectric layer covers the gate electrode; and the second electrode comprises a source electrode and a drain electrode locating over the gate dielectric layer.

6. The electronic device including a bio-polymer material as claimed in claim 5, further comprising an organic semiconductor layer, wherein the organic semiconductor layer covers the gate dielectric layer; or the organic semiconductor layer covers the gate dielectric layer, the source electrode, and the drain electrode.

7. The electronic device including a bio-polymer material as claimed in claim 6, wherein the electronic device is a top contact organic thin film transistor; the organic semiconductor layer covers the entire surface of the gate dielectric layer, and the source electrode and the drain electrode locate on the organic semiconductor layer.

8. The electronic device including a bio-polymer material as claimed in claim 6, wherein the electronic device is a bottom contact organic thin film transistor, the organic semiconductor layer covers the gate dielectric layer, the source electrode, and the drain electrode, and the source electrode and the drain electrode locate on the gate dielectric layer.

9. The electronic device including a bio-polymer material as claimed in claim 6, wherein the material of the organic semiconductor layer is selected from pentacene, PTCDI-C8, fullerene (C60), F₁₆CuPc, or pentacene derivatives.

10. The electronic device including a bio-polymer material as claimed in claim 6, further comprising a buffering layer disposed on the gate dielectric layer, and the buffering layer is made of pentacene.

11. The electronic device including a bio-polymer material as claimed in claim 6, further comprising a floating gate electrode disposed between the gate dielectric layer and the organic semiconductor layer, wherein the floating gate electrode locates on the gate-dielectric layer, and the material of the floating gate electrode is selected from Al, Cu, Cr, Ag, Pt, Au, Zn, In or Sn.

12. The electronic device including a bio-polymer material as claimed in claim 11, further comprising a dielectric layer disposed between the floating gate electrode layer and the organic semiconductor layer, the dielectric layer covers the floating gate electrode, and the material of the dielectric layer is made of a bio-polymer material selected from a group consisting of wool keratin, collagen hydrolysate, gelatin, whey protein and hydroxypropyl methylcellulose.

13. The electronic device including a bio-polymer material as claimed in claim 1, wherein the bio-polymer layer is an insulating layer; the first electrode disposes between the substrate and the insulating layer, and the insulating layer covers the first electrode; and the second electrode disposed over the insulating layer.

14. The electronic device including a bio-polymer material as claimed in claim 1, wherein the electronic device comprises an organic thin film transistor, an organic floating gate memory, or a metal-insulator-metal capacitor.

15. A method for manufacturing an electronic device including a bio-polymer material, comprising the following steps:
(A) providing a substrate;
(B) forming a first electrode on the substrate;
(C) coating the substrate having the first electrode formed thereon with a bio-polymer solution to obtain a bio-polymer layer on the substrate and the first electrode; and
(D) forming a second electrode over the bio-polymer layer.

16. The method as claimed in claim 15, wherein the bio-polymer layer is a gate dielectric layer; the first electrode is a gate electrode; and the second electrode comprises a source electrode and a drain electrode.

17. The method as claimed in claim 16, further comprises forming an organic semiconductor layer on the gate dielectric layer.

18. The method as claimed in claim 17, wherein the material of the organic semiconductor includes pentacene, PTCDI-C8, fullerene (C60), F₁₆CuPc, or pentacene derivatives.

19. The method as claimed in claim 17, wherein the organic semiconductor layer covers the entire surface of the gate dielectric layer, with the source electrode and the drain electrode disposed on the organic semiconductor layer to obtain a top contact organic thin film transistor.

20. The method as claimed in claim 17, wherein the source electrode and the drain electrode are disposed on the gate dielectric layer, and the organic semiconductor layer covers the gate dielectric layer, the source electrode, and the drain electrode to obtain a bottom contact organic thin film transistor.

21. The method as claimed in claim 17, wherein further comprising a step: forming a buffer layer on the gate dielectric layer before forming the organic semiconductor layer.

22. The method as claimed in claim 17, wherein further comprising a step: forming a floating gate electrode on the gate dielectric layer before forming the organic semiconductor layer.

23. The method as claimed in claim 22, wherein after forming the floating gate electrode, a dielectric layer is formed on the floating gate electrode; the dielectric layer disposes between the floating gate electrode and the semiconductor layer and covers the floating gate electrode.

24. The method as claimed in claim 15, wherein the step (C) comprises the flowing steps:
(C1) providing a bio-polymer solution;
(C2) coating the substrate having the gate electrode formed thereon with the bio-polymer solution, or dipping the substrate having the gate electrode formed thereon into the bio-polymer solution; and
(C3) drying the bio-polymer solution which is coated or dipped on the substrate to obtain a bio-polymer layer on the substrate and the electrode.

25. The method as claimed in claim 15, wherein the bio-polymer layer is an insulating layer.

26. A method for manufacturing a metal-insulator-metal capacitor, comprising the following steps:
(a) providing a substrate;
(b) forming a first electrode on the substrate;
(c) coating the substrate having the first electrode formed thereon with a bio-polymer solution to obtain an insulating layer on the substrate and the first electrode; and
(d) forming a second electrode on the insulating layer.

27. The method as claimed in claim 26, wherein the step (c) comprises the flowing steps:
(c1) providing a bio-polymer solution;
(c2) coating the substrate having the first electrode formed thereon with the bio-polymer solution, or dipping the substrate having the first electrode formed thereon into the bio-polymer solution; and
(c3) drying the bio-polymer solution which is coated or dipped on the substrate to obtain an insulating layer on the substrate and the first electrode.
